(19) United States
(12) Patent Application Publication
(10) Pub. No.: US 2026/0129751 A1
(43) Pub. Date: May 7, 2026

(54) PRINTED CIRCUIT BOARD

(71) Applicant: SUMITOMO ELECTRIC PRINTED CIRCUITS, INC., Shiga (JP)

(72) Inventors: Katsuya MORIZANE, Shiga (JP); Takuto NISHI, Shiga (JP); Yukinori NISHIMURA, Shiga (JP)

(73) Assignee: SUMITOMO ELECTRIC PRINTED CIRCUITS, INC., Shiga (JP)

(21) Appl. No.: 19/378,839

(22) Filed: Nov. 4, 2025

(30) Foreign Application Priority Data
Nov. 6, 2024 (JP) 2024-194532

(51) Int. Cl. H05K 1/02; H05K 1/03

(52) U.S. Cl. CPC H05K 1/0278; H05K 1/036; H05K 2201/015; H05K 2201/0195; H05K 2201/0275

(57) ABSTRACT

A printed circuit board includes a bendable portion. The bendable portion is bendable in a bending direction in plan view and has a first dielectric layer, a signal pattern, a second dielectric layer, a cloth, and a ground pattern. The first dielectric layer has a first main surface. The signal pattern is arranged on the first main surface. The second dielectric layer has a second main surface and a third main surface opposite to the second main surface, and the second main surface is arranged to face the first main surface. The cloth includes a plurality of first reinforced fibers extending in a first direction in plan view and a plurality of second reinforced fibers extending in a second direction inclined with respect to the first direction in plan view, the plurality of first reinforced fibers and the plurality of second reinforced fibers being knitted together in a cloth form.

### CROSS REFERENCE TO RELATED APPLICATIONS

This application claims priority based on Japanese Patent Application No. 2024-194532 filed on November 6, 2024, and the entire contents of the Japanese patent application are incorporated herein by reference.

### TECHNICAL FIELD

The present disclosure relates to a printed circuit board.

### BACKGROUND

Japanese Unexamined Patent Application Publication No. 2011-54919 (Patent literature 1) describes a printed circuit board. The printed circuit board described in Patent Literature 1 includes a first dielectric layer, a signal pattern disposed on the first dielectric layer, an adhesion layer disposed on the first dielectric layer so as to cover the signal pattern, a second dielectric layer disposed on the adhesion layer, and a ground pattern disposed on the second dielectric layer.

### SUMMARY

A printed circuit board of the present disclosure includes a bendable portion. The bendable portion is bendable in a bending direction in plan view and has a first dielectric layer, a signal pattern, a second dielectric layer, a cloth, and a ground pattern. The first dielectric layer has a first main surface. The signal pattern is arranged on the first main surface. The second dielectric layer has a second main surface and a third main surface opposite to the second main surface, and the second main surface is arranged to face the first main surface. The cloth includes a plurality of first reinforced fibers extending in a first direction in plan view and a plurality of second reinforced fibers extending in a second direction inclined with respect to the first direction in plan view, the plurality of first reinforced fibers and the plurality of second reinforced fibers being knitted together in a cloth form. The cloth is arranged inside the second dielectric layer. The ground pattern is arranged on the third main surface. Each of the first direction and the second direction is inclined with respect to the bending direction.

### BRIEF DESCRIPTION OF THE DRAWINGS

FIG. 1 is a schematic side view of a printed circuit board 100.

FIG. 2 is a plan view of the printed circuit board 100.

FIG. 3 is a cross-sectional view taken along line III-III in FIG. 2.

FIG. 4 is a schematic view showing the orientations of a reinforced fiber 51a and a reinforced fiber 51b in a cloth 51 arranged inside a dielectric layer 50 in a bendable portion 10 of the printed circuit board 100.

FIG. 5 is a cross-sectional view of the printed circuit board 100 according to a modification 1.

FIG. 6 is a cross-sectional view of the printed circuit board 100 according to a modification 2.

FIG. 7 is a manufacturing process diagram of the printed circuit board 100.

FIG. 8 is a first cross-sectional view for explaining a preparation step S1.

FIG. 9 is a second explanatory view for explaining the preparation step S1.

FIG. 10 is a cross-sectional view for explaining a patterning step S2.

FIG. 11 is a schematic view showing the orientations of the reinforced fiber 51a and the reinforced fiber 51b in the cloth 51 arranged inside the dielectric layer 50 in the bendable portion 10 of a printed circuit board 200.

FIG. 12 shows load-strain curves for samples when changing an angle formed by the longitudinal direction and a first direction DR1.

FIG. 13 is a graph showing a relationship between an angle formed by the longitudinal direction of each sample and a first direction DR1 and a breaking strain.

### DETAILED DESCRIPTION

When the printed circuit board described in Patent Literature 1 is bent such that the second dielectric layer is located on the inner side of the bend compared to the first dielectric layer, compressive stress acts on the second dielectric layer. When the second dielectric layer buckles due to the compressive stress, the distance between the signal pattern and the ground pattern changes, and thus the impedance of the signal pattern changes. As a result, transmission characteristics of a high frequency signal in the signal pattern deteriorate. The present disclosure provides a printed circuit board capable of improving transmission characteristics of a high frequency signal in a signal pattern.

### Description of Embodiments of Present Disclosure

First, embodiments of the present disclosure will be listed and described.

(1) A printed circuit board according to an embodiment includes a bendable portion. The bendable portion is bendable in a bending direction in plan view and has a first dielectric layer, a signal pattern, a second dielectric layer, a cloth, and a ground pattern. The first dielectric layer has a first main surface. The signal pattern is arranged on the first main surface. The second dielectric layer has a second main surface and a third main surface opposite to the second main surface, and the second main surface is arranged to face the first main surface. The cloth includes a plurality of first reinforced fibers extending in a first direction in plan view and a plurality of second reinforced fibers extending in a second direction inclined with respect to the first direction in plan view, the plurality of first reinforced fibers and the plurality of second reinforced fibers being knitted together in a cloth form. The cloth is arranged inside the second dielectric layer. The ground pattern is arranged on the third main surface. Each of the first direction and the second direction is inclined with respect to the bending direction. According to the printed circuit board of the above (1), it is possible to improve transmission characteristics of a high frequency signal in the signal pattern.

(2) In the printed circuit board according to the above (1), the first direction may be perpendicular to the second direction.

(3) In the printed circuit board according to the above (2), an angle formed by the first direction and the bending direction in plan view may be 30° or more.

(4) In the printed circuit board according to the above (2) or (3), an angle formed by the first direction and the bending direction in plan view may be 40° or more.

(5) In the printed circuit board according to any one of the above (1) to (4), the plurality of first reinforced fibers and the plurality of second reinforced fibers may be made of glass.

(6) In the printed circuit board according to any one of the above (1) to (5), the second dielectric layer may be made of a fluororesin.

(7) The printed circuit board according to any one of the above (1) to (6) may further include an adhesion layer arranged between the first main surface and the second main surface to cover the signal pattern.

(8) The printed circuit board according to any one of the above (1) to (7) may further include a second cloth arranged inside the second dielectric layer. The second cloth may include a plurality of third reinforced fibers extending in a third direction in plan view and a plurality of fourth reinforced fibers extending in a fourth direction inclined with respect to the third direction in plan view, the plurality of third reinforced fibers and the plurality of fourth reinforced fibers being knitted together in a cloth form. Each of the third direction and the fourth direction may be inclined with respect to the bending direction.

(9) In the printed circuit board according to any one of the above (1) to (8), the bendable portion may be bendable such that the second dielectric layer is compressed.

### Details of Embodiments of Present Disclosure

The details of the embodiments of the present disclosure will be described with reference to the drawings. In the following drawings, the same or corresponding parts are denoted by the same reference numerals, and redundant description will not be repeated. A printed circuit board according to an embodiment is referred to as a printed circuit board 100.

### Configuration of Printed Circuit Board100

The configuration of the printed circuit board 100 will be described below.

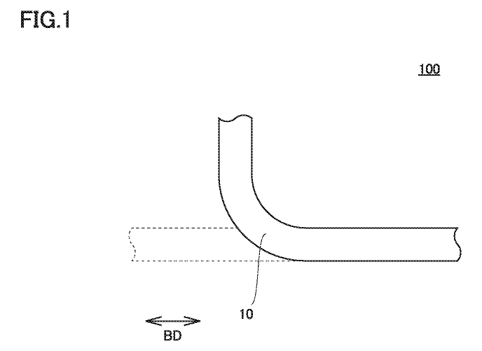

As shown in FIG. 1, the printed circuit board 100 has a bendable portion 10. The bendable portion 10 is bendable in a bending direction BD in plan view.

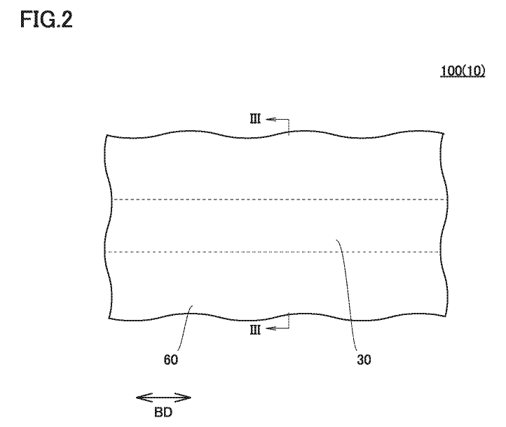

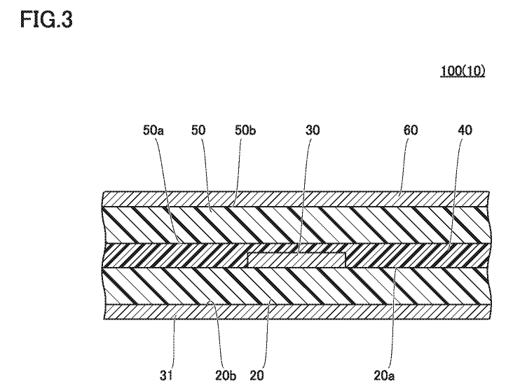

As shown in FIGS. 2 and 3, the printed circuit board 100 includes a dielectric layer 20, a signal pattern 30, a ground pattern 31, an adhesion layer 40, a dielectric layer 50, and a ground pattern 60 in the bendable portion 10.

The dielectric layer 20 has a main surface 20a and a main surface 20b. The main surface 20b is a surface opposite to the main surface 20a. The main surface 20a and the main surface 20b are end surfaces in a thickness direction of the dielectric layer 20. The dielectric layer 20 is made of a dielectric material. The dielectric layer 20 is made of, for example, a fluororesin.

The signal pattern 30 is arranged on the dielectric layer 20 (main surface 20a). The signal pattern 30 extends in, for example, the bending direction BD in plan view. For example, a high frequency signal flows through the signal pattern 30. The signal pattern 30 is made of a conductive material. The signal pattern 30 is made of, for example, copper or a copper alloy.

The ground pattern 31 is arranged on the dielectric layer 20 (main surface 20b). The ground pattern 31 is at a ground potential. The ground pattern 31 is made of a conductive material. The ground pattern 31 is made of, for example, copper or a copper alloy.

The adhesion layer 40 is arranged on the dielectric layer 20 (main surface 20a) to cover the signal pattern 30. The adhesion layer 40 is made of an adhesive.

The dielectric layer 50 has a main surface 50a and a main surface 50b. The main surface 50b is a surface opposite to the main surface 50a. The main surface 50a and the main surface 50b are end surfaces in a thickness direction of the dielectric layer 50. The dielectric layer 50 is arranged on the adhesion layer 40 such that the main surface 50a faces the adhesion layer 40. The bendable portion 10 is bent such that the dielectric layer 50 is located on the inner side of the bend, compared to the dielectric layer 20.

The ground pattern 60 is arranged on the dielectric layer 50 (main surface 50b). The ground pattern 60 is at a ground potential. The ground pattern 60 is made of a conductive material. The ground pattern 60 is made of, for example, copper or a copper alloy.

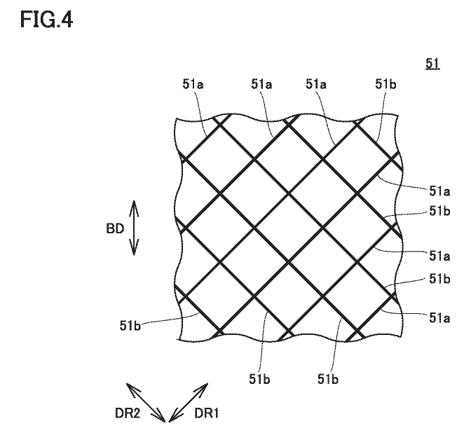

A cloth 51 is arranged inside the dielectric layer 50. As shown in FIG. 4, the cloth 51 has a plurality of reinforced fibers 51a extending in a first direction DR1 in plan view, and a plurality of reinforced fibers 51b extending in a second direction DR2 inclined with respect to the first direction DR1 in plan view. The cloth 51 is formed by knitting the plurality of reinforced fibers 51a and the plurality of reinforced fibers 51b together in a cloth form. The reinforced fiber 51a and the reinforced fiber 51b are made of, for example, glass (glass fiber). That is, the cloth 51 is, for example, a glass cloth.

In plan view, an angle formed by the first direction DR1 and the second direction DR2 is, for example, 90°. As long as the first direction DR1 is inclined with respect to the second direction DR2 in plan view, the angle formed by the first direction DR1 and the second direction DR2 in plan view may not be 90°.

In plan view, the first direction DR1 and the second direction DR2 are inclined with respect to the bending direction BD. An angle formed by the first direction DR1 and the bending direction BD in plan view is, for example, 15° or more. The angle formed by the first direction DR1 and the bending direction BD in plan view may be 30° or more, or 40° or more. When the angle formed by the first direction DR1 and the bending direction BD in plan view is 90°, the angle formed by the first direction DR1 and the second direction DR2 in plan view is ideally 45°. Note that the smaller angle of the two angles formed by the first direction DR1 and the bending direction BD in plan view is used as the angle formed by the first direction DR1 and the bending direction BD in plan view.

Although not shown, a cloth may be arranged inside the dielectric layer 20. The reinforced fibers forming the cloth arranged inside the dielectric layer 20 may also be oriented in a manner similar to the reinforced fibers 51a and the reinforced fibers 51b. That is, the extending direction of one of the reinforced fibers forming the cloth arranged inside the dielectric layer 20 and the extending direction of the other reinforced fiber forming the cloth arranged inside the dielectric layer 20 are inclined with respect to the bending direction BD. The extending direction of the one reinforced fiber may be parallel to the first direction DR1 or may not be parallel to the first direction DR1. The extending direction of the other reinforced fiber may be parallel to the second direction DR2 or may not be parallel to the second direction DR2.

### Modification 1

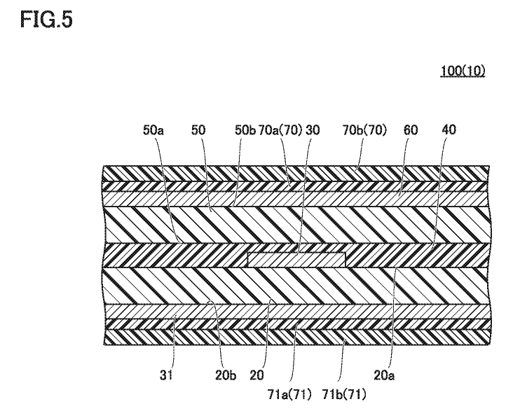

As shown in FIG. 5, the printed circuit board 100 may further include a cover lay 70 and a cover lay 71. The cover lay 70 includes an adhesion layer 70a and a film 70b. The adhesion layer 70a is arranged on the ground pattern 60. The film 70b is arranged on the adhesion layer 70a. The cover lay 71 includes an adhesion layer 71a and a film 71b. The adhesion layer 71a is arranged on the ground pattern 31. The film 71b is arranged on the adhesion layer 71a.

### Modification 2

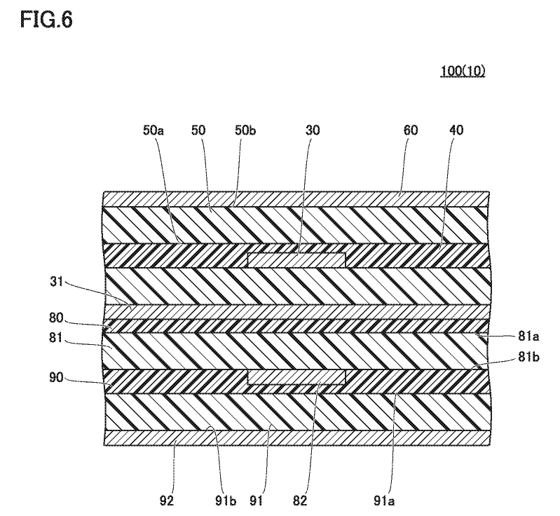

As shown in FIG. 6, the printed circuit board 100 may further include an adhesion layer 80, a dielectric layer 81, a signal pattern 82, an adhesion layer 90, a dielectric layer 91, and a ground pattern 92.

The adhesion layer 80 is arranged on the ground pattern 31. The adhesion layer 80 is made of an adhesive. The dielectric layer 81 has a main surface 81a and a main surface 81b opposite to the main surface 81a, and is arranged on the adhesion layer 80 such that the main surface 81a faces the adhesion layer 80. The dielectric layer 81 is made of a dielectric material, for example, a fluororesin. The signal pattern 82 is arranged on the main surface 81b. The signal pattern 82 is made of a conductive material, for example, copper or a copper alloy.

The adhesion layer 90 is arranged on the main surface 81b to cover the signal pattern 82. The adhesion layer 90 is made of an adhesive. The dielectric layer 91 has a main surface 91a and a main surface 91b opposite to the main surface 91a, and is arranged on the adhesion layer 90 such that the main surface 91a faces the adhesion layer 90. The dielectric layer 91 is made of a dielectric material, for example, a fluororesin. The ground pattern 92 is arranged on the main surface 91b. The ground pattern 92 is made of a conductive material, for example, copper or a copper alloy. In this manner, a plurality of layers of signal patterns may be arranged in inner layers of the printed circuit board 100.

### Method for Manufacturing Printed Circuit Board 100

A method for manufacturing the printed circuit board 100 will be described below.

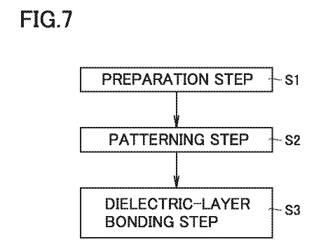

As shown in FIG. 7, the method for manufacturing the printed circuit board 100 includes a preparation step S1, a patterning step S2, and a dielectric-layer bonding step S3. The patterning step S2 is performed after the preparation step S1, and the dielectric-layer bonding step S3 is performed after the patterning step S2.

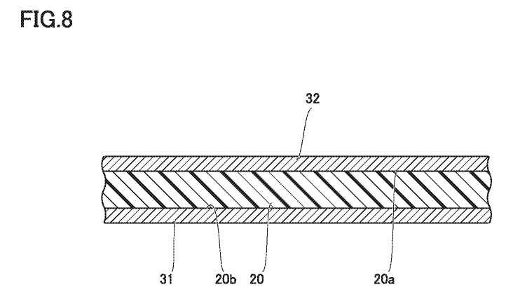

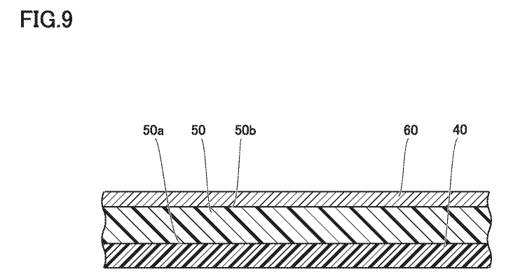

As shown in FIG. 8, in the preparation step S1, the dielectric layer 20 is prepared. In the dielectric layer 20 prepared in the preparation step S1, a copper layer 32 is arranged on the main surface 20a, and the ground pattern 31 is arranged on the main surface 20b. As shown in FIG. 9, in the preparation step S1, the dielectric layer 50 is also prepared. In the dielectric layer 50 prepared in the preparation step S1, the adhesion layer 40 is arranged on the main surface 50a, and the ground pattern 60 is arranged on the main surface 50b. At this stage, the adhesion layer 40 is uncured.

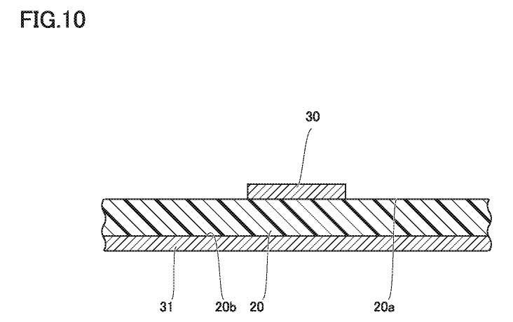

As shown in FIG. 10, in the patterning step S2, the copper layer 32 is patterned to form the signal pattern 30. In the patterning step S2, first, a resist pattern is formed on the copper layer 32. The resist pattern is formed by, for example, bonding a dry film resist on the copper layer 32 and exposing and developing the dry film resist. Second, the copper layer 32 exposed from an opening of the resist pattern is removed by etching. As a result, the copper layer 32 is patterned to form the signal pattern 30.

In the dielectric-layer bonding step S3, the dielectric layer 50 is bonded. In the dielectric-layer bonding step S3, first, the dielectric layer 50 is arranged so that the adhesion layer 40 covers the signal pattern 30. Second, the dielectric layer 50 is hot-pressed against the dielectric layer 20. That is, the dielectric layer 50 is pressed toward the dielectric layer 20 in a heated state. As a result, the adhesion layer 40 is cured, and the dielectric layer 50 is bonded to the dielectric layer 20 with the adhesion layer 40. As described above, the structure of the printed circuit board 100 shown in FIGS. 2 and 3 is formed.

### Effects of Printed Circuit Board 100

Hereinafter, the effects of the printed circuit board 100 will be described in comparison with a printed circuit board according to a comparative example. Note that the printed circuit board according to the comparative example is referred to as a printed circuit board 200.

Fluororesin has a low dielectric constant, and is thus suitable as a material used for the dielectric layer 50 from the viewpoint of improving transmission characteristics of the high frequency signal flowing through the signal pattern 30. However, fluororesin has a large coefficient of thermal expansion. Thus, in order to suppress the thermal expansion of the dielectric layer 50, it is conceivable to arrange the cloth 51 inside the dielectric layer 50.

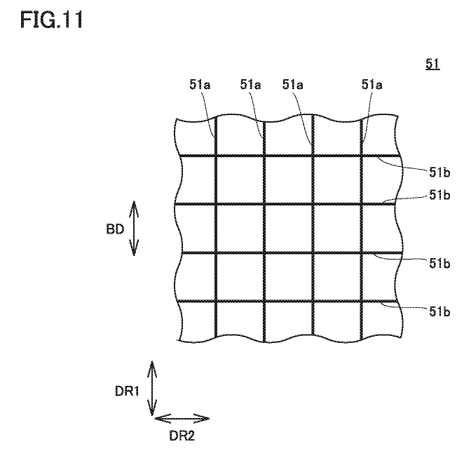

As shown in FIG. 11, in the bendable portion 10 of the printed circuit board 200, the first direction DR1 is parallel to the bending direction BD and the second direction DR2 is perpendicular to the bending direction BD in plan view. The bendable portion 10 is bent such that the dielectric layer 50 is located on the inner side of the bend, compared to the dielectric layer 20. Thus, in the printed circuit board 200, compressive stress acts on the cloth 51 arranged inside the dielectric layer 50 as the bendable portion 10 is bent. In addition, since the first direction DR1 is parallel to the bending direction BD in the bendable portion 10 of the printed circuit board 200, the reinforced fiber 51a is buckled by the compressive stress, and thus, the dielectric layer 50 and the ground pattern 60 arranged on the main surface 50b are also buckled. As a result, in the printed circuit board 200, the distance between the ground pattern 60 and the signal pattern 30 changes, and thus the impedance of the signal pattern 30 changes.

On the other hand, in the bendable portion 10 of the printed circuit board 100, both the first direction DR1 and the second direction DR2 are inclined with respect to the bending direction BD in plan view. Thus, the compressive stress is not concentrated on one of the reinforced fiber 51a or the reinforced fiber 51b, and buckling of the reinforced fiber 51a and the reinforced fiber 51b is less likely to occur. Thus, according to the printed circuit board 100, the distance between the ground pattern 60 and the signal pattern 30 and the impedance of the signal pattern 30 are less likely to change, and signal transmission characteristics of the signal pattern 30 are improved.

In order to investigate the influence of the angle formed by the first direction DR1 and the bending direction BD in plan view on a load-strain curve of the dielectric layer 50, sample 1 to sample 4 were prepared as samples of the dielectric layer 50. Each sample was a rectangle of 10mm × 50mm in plan view. In each sample, the direction in which the length is 50mm is referred to as the longitudinal direction.

In the sample 1, the angle formed by the first direction DR1 and the longitudinal direction in plan view was set to 0° (the first direction DR1 was parallel to the bending direction BD). In the sample 2, the angle formed by the first direction DR1 and the longitudinal direction in plan view was set to 15°. In the sample 3, the angle formed by the first direction DR1 and the longitudinal direction in plan view was set to 30°. In the sample 4, the angle formed by the first direction DR1 and the longitudinal direction in plan view was set to 45°. In each of the samples 1 to 4, the angle formed by the first direction DR1 and the second direction DR2 in plan view was 90°.

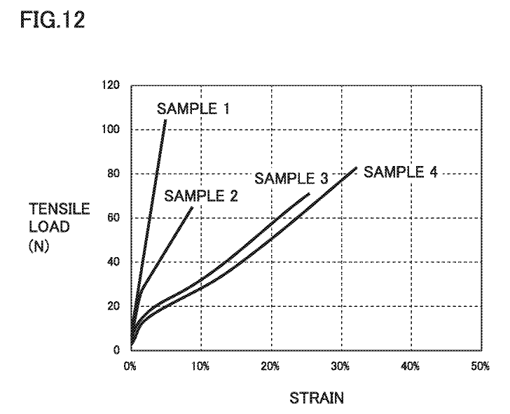

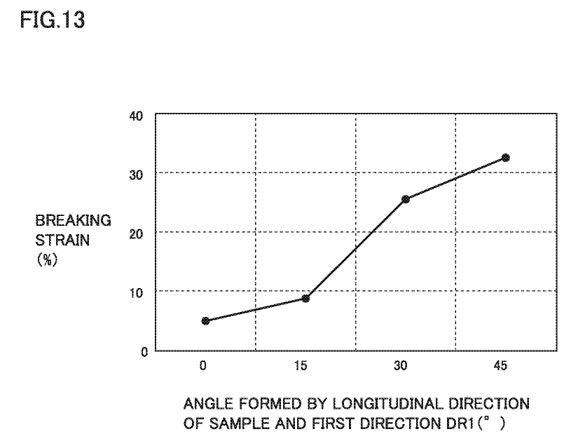

A tensile test was performed on the samples 1 to 4. In the tensile test, each sample was pulled along the longitudinal direction, and a load-strain curve was obtained. As shown in FIGS. 12 and 13, a breaking strain of each sample increased as the angle formed by the longitudinal direction and the first direction DR1 in plan view increased.

When the bendable portion 10 is bent, tensile stress is applied to the dielectric layer 20. From the results of FIG. 12 and FIG. 13, it was found that the stress is less likely to concentrate on one of the reinforced fibers forming the cloth arranged inside the dielectric layer 20, and the reinforced fiber is less likely to be broken. In addition, when the bendable portion 10 is bent, compressive stress is applied to the dielectric layer 50, and the dielectric layer 50 is going to be buckled, but as in the case where the tensile stress is applied, the stress is less likely to be concentrated on one of the reinforced fibers forming the cloth arranged inside the dielectric layer 50, and thus the buckling of the reinforced fiber is less likely to occur. As described above, it was found that, when the first direction DR1 and the second direction DR2 are inclined with respect to the bending direction BD in plan view, the buckling of the dielectric layer 50 and thus the impedance of the signal pattern 30 are less likely to change, and the signal transmission characteristics of the signal pattern 30 are improved.

The embodiments disclosed herein are to be considered in all respects as illustrative and not restrictive. The scope of the present invention is defined by the terms of the claims, rather than the embodiments described above, and is intended to include any modifications within the scope and meaning equivalent to the terms of the claims.

What is claimed is:

1. A printed circuit board comprising:
a bendable portion,
wherein the bendable portion is bendable in a bending direction in plan view and has a first dielectric layer, a signal pattern, a second dielectric layer, a first cloth, and a ground pattern,
wherein the first dielectric layer has a first main surface,
wherein the signal pattern is arranged on the first main surface,
wherein the second dielectric layer has a second main surface and a third main surface opposite to the second main surface, and the second main surface is arranged to face the first main surface,
wherein the first cloth includes a plurality of first reinforced fibers extending in a first direction in plan view and a plurality of second reinforced fibers extending in a second direction inclined with respect to the first direction in plan view, the plurality of first reinforced fibers and the plurality of second reinforced fibers being knitted together in a cloth form,
wherein the first cloth is arranged inside the second dielectric layer,
wherein the ground pattern is arranged on the third main surface, and
wherein each of the first direction and the second direction is inclined with respect to the bending direction.

2. The printed circuit board according to claim 1,
wherein the first direction is perpendicular to the second direction.

3. The printed circuit board according to claim 2,
wherein an angle formed by the first direction and the bending direction in plan view is 30° or more.

4. The printed circuit board according to claim 2,
wherein an angle formed by the first direction and the bending direction in plan view is 40° or more.

5. The printed circuit board according to claim 1,
wherein the plurality of first reinforced fibers and the plurality of second reinforced fibers are made of glass.

6. The printed circuit board according to claim 1,
wherein the second dielectric layer is made of a fluororesin.

7. The printed circuit board according to claim 1, further comprising:
an adhesion layer arranged between the first main surface and the second main surface to cover the signal pattern.

8. The printed circuit board according to claim 1, further comprising:
a second cloth arranged inside the first dielectric layer,
wherein the second cloth includes a plurality of third reinforced fibers extending in a third direction in plan view and a plurality of fourth reinforced fibers extending in a fourth direction inclined with respect to the third direction in plan view, the plurality of third reinforced fibers and the plurality of fourth reinforced fibers being knitted together in a cloth form, and
wherein each of the third direction and the fourth direction is inclined with respect to the bending direction.

9. The printed circuit board according to claim 1,
wherein the bendable portion is bendable such that the second dielectric layer is compressed.
